(19) United States
(12) Patent Application Publication
(10) Pub. No.: US 2026/0163583 A1
(43) Pub. Date: Jun. 11, 2026

(54) ANALOG TO DIGITAL CONVERSION DEVICE AND ANALOG TO DIGITAL CONVERSION METHOD

(71) Applicant: REALTEK SEMICONDUCTOR CORPORATION, HSINCHU (TW)

(72) Inventor: WEI-CIAN HONG, Hsinchu (TW)

(21) Appl. No.: 19/413,268

(22) Filed: Dec. 9, 2025

(30) Foreign Application Priority Data
Dec. 10, 2024 (TW) 113147983

(51) Int. Cl. H03M 1/50

(52) U.S. Cl. CPC H03M 1/50

(57) ABSTRACT

An analog to digital conversion device includes a first slope signal generator circuit, a second slope signal generator circuit, and a comparator circuit. The first slope signal generator circuit is configured to generate a first slope signal, wherein the first slope signal repeatedly ramps up and down within a voltage range with at least one first slope. The second slope signal generator circuit is configured to generate a second slope signal, wherein the second slope signal repeatedly ramps up and down within the voltage range with at least one second slope, and the at least one first slope and the at least one second slope are negatively related. The comparator circuit is configured to generate an output signal according to the first slope signal, the second slope signal, and an input signal.

### BACKGROUND OF THE INVENTION

### 1. Field of the Invention

The present disclosure relates to an analog to digital conversion device and an analog to digital conversion method, especially to an analog to digital conversion device and an analog to digital conversion method that can reduce operation latency.

### 2. Description of Related Art

Analog to digital converters (ADCs) are commonly used in electronic devices to convert analog signals into digital signals that can be processed by electronic devices. A time-interleaved slope ADC is a type of ADC. However, due to operating conditions of time-interleaved slope ADCs, operation of time-interleaved slope ADCs exhibits latency.

### SUMMARY OF THE INVENTION

In some aspects, an object of the present disclosure is to, but not limited to, provides an analog to digital conversion device and an analog to digital conversion method that makes an improvement to the prior art.

An embodiment of an analog to digital conversion device includes a first slope signal generator circuit, a second slope signal generator circuit, and a comparator circuit. The first slope signal generator circuit is configured to generate a first slope signal, wherein the first slope signal repeatedly ramps up and down within a voltage range with at least one first slope. The second slope signal generator circuit is configured to generate a second slope signal, wherein the second slope signal repeatedly ramps up and down within the voltage range with at least one second slope, and the at least one first slope and the at least one second slope are negatively related. The comparator circuit is configured to generate an output signal according to the first slope signal, the second slope signal, and an input signal.

An embodiment of an analog to digital conversion method includes generating a first slope signal by a first slope signal generator circuit, wherein the first slope signal repeatedly ramps up and down within a voltage range with at least one first slope; generating a second slope signal by a second slope signal generator circuit, wherein the second slope signal repeatedly ramps up and down within the voltage range with at least one second slope, and the at least one first slope and the at least one second slope are negatively related; and generating an output signal according to the first slope signal, the second slope signal, and an input signal by a comparator circuit.

Technical features of some embodiments of the present disclosure make an improvement to the prior art. The analog to digital conversion device and the analog to digital conversion method of the present disclosure can reduce operation latency.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of an analog to digital conversion device of the present disclosure.

FIG. 2 shows an embodiment of a flow diagram of an analog to digital conversion method of the present disclosure.

FIG. 3 shows an embodiment of a timing diagram of an analog to digital conversion device of the present disclosure.

### DETAILED DESCRIPTION OF THE PREFERRED EMBODIMENTS

To address the issue of operation latency in time-interleaved slope analog to digital converters (ADCs) in the prior art, the present disclosure provides an analog to digital conversion device and an analog to digital conversion method, which will be explained in detail as shown below.

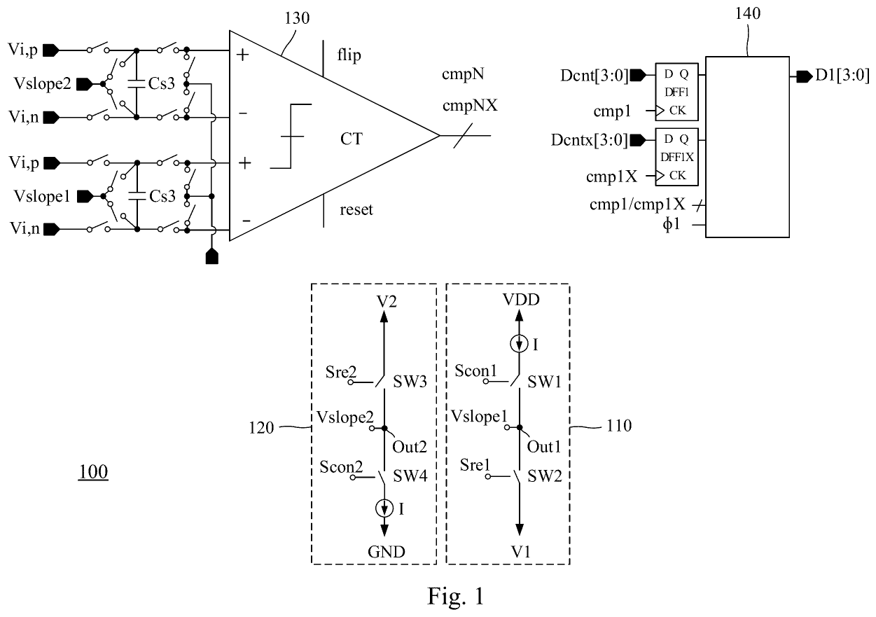

FIG. 1 shows an embodiment of an analog to digital conversion device 100 of the present disclosure. As shown in the figure, the analog to digital conversion device 100 includes a first slope signal generator circuit 110, a second slope signal generator circuit 120, a comparator circuit 130, a capacitor Cs3, flip-flops DFF1, DFF1X, and a digital logic processor 140.

In some embodiments, the analog to digital conversion device 100 may be, but is not limited to, a time-interleaved slope analog to digital converter, and the operation of the analog to digital conversion device 100 is described as follows. The analog to digital conversion device 100 may sample an input signal using the capacitor Cs3. Subsequently, the comparator circuit 130 compares the sampled signal with a first slope signal Vslope1 and a second slope signal Vslope2 generated by the first slope signal generator circuit 110 and the second slope signal generator circuit 120. Before the comparator circuit 130 generates a comparison result, a counter continues counting a count value Dcnt[3:0] until the comparator circuit 130 generates the comparison result. When the positive terminal of the comparator circuit 130 becomes greater than the negative terminal, the output signal cmpN generated by the comparator circuit 130 transitions from low to high. The rising edge of the output signal cmpN transitioning from low to high triggers the flip-flops (e.g., flip-flops DFF1, DFF1X), and the flip-flops store the current count values (e.g., Dcnt[3:0], Dcntx[3:0]) and transmit them to the digital logic processor 140. After being processed by the digital logic processor 140, a data signal D1[3:0] is generated. As described above, the analog to digital conversion device 100 completes a conversion cycle.

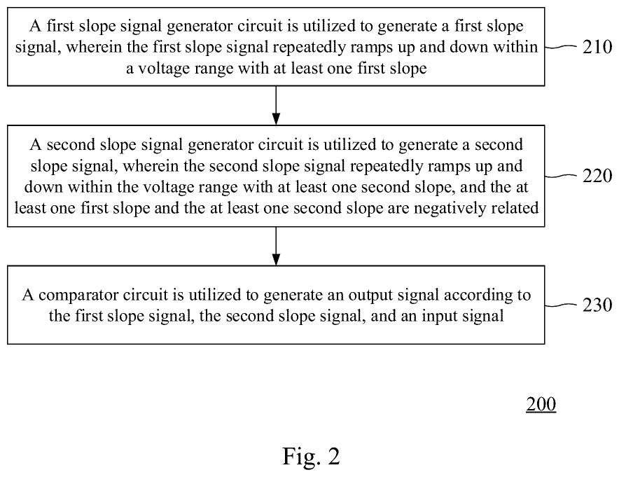

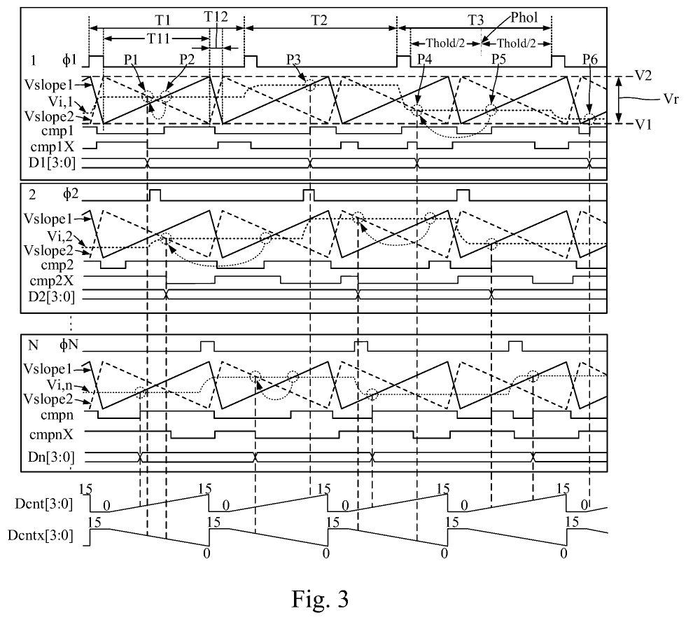

To illustrate how the analog to digital conversion device 100 of the present disclosure reduces operation latency, please refer to FIGS. 2 and 3. FIG. 2 shows an embodiment of a flow diagram of an analog to digital conversion method 200 of the present disclosure. FIG. 3 shows an embodiment of a timing diagram of the analog to digital conversion device 100 of the present disclosure.

Referring to step 210 of FIG. 2, a first slope signal generator circuit is utilized to generate a first slope signal, wherein the first slope signal repeatedly ramps up and down within a voltage range with at least one first slope. For example, referring to FIGS. 1, 3, the first slope signal generator circuit 110 generates a first slope signal Vslope1. The first slope signal Vslope1 ramps up with a slope and ramps down with another slope within the voltage range Vr to complete one up-and-down cycle, and the first slope signal Vslope1 repeatedly ramps up and down within the voltage range Vr in a periodic manner.

Referring to step 220 of FIG. 2, a second slope signal generator circuit is utilized to generate a second slope signal, wherein the second slope signal repeatedly ramps up and down within the voltage range with at least one second slope, and the at least one first slope and the at least one second slope are negatively related. For example, referring to FIGS. 1, 3, the second slope signal generator circuit 120 generates a second slope signal Vslope2. The second slope signal Vslope2 ramps up with a slope and ramps down with another slope within the voltage range Vr to complete one up-and-down cycle, and the second slope signal Vslope2 repeatedly ramps up and down within the voltage range Vr in a periodic manner. As shown in the figure, the slope of the first slope signal Vslope1 is negatively correlated with the slope of the second slope signal Vslope2.

Referring to step 230 of FIG. 2, a comparator circuit is utilized to generate an output signal according to the first slope signal, the second slope signal, and an input signal. For example, referring to FIGS. 1, 3, using the input signal Vi,1 as an example, the comparator circuit 130 generates output signals cmp1, com1X according to the first slope signal Vslope1, the second slope signal Vslope2, and the input signal Vi,1.

Specifically, referring to period T3, at point P4, the comparator circuit 130 generates an output signal com1X according to the second slope signal Vslope2 and the input signal Vi,1. At this time, the digital output provides a count result of Dcntx[3:0]. As shown in the figure, after the analog to digital conversion device 100 of the present disclosure adds the second slope signal Vslope2, the point P4 where the output signal is generated occurs before a time point Phol, wherein the time point Phol is located at the midpoint of a hold period (Thold/2). Furthermore, if the analog to digital conversion device 100 of the present disclosure adopts only the first slope signal Vslope1, the point P5 where the output signal is generated occurs after the time point Phol. This demonstrates that the conversion time of the present disclosure is shortened to be less than half of the hold period (Thold/2).

In view of the above, compared to using only a single slope signal, the analog to digital conversion device 100 of the present disclosure uses two slope signals (e.g., the first slope signal Vslope1 and the second slope signal Vslope2), which shortens the conversion time to be less than half of the hold period (Thold/2). In other words, the operational latency of the present disclosure is reduced to be less than half of the hold period (Thold/2).

Some embodiments of the present disclosure will be described in detail below. However, the present disclosure is not limited to the embodiments described below, which are merely configured to illustrate the technical concepts of the present disclosure for ease of understanding.

Referring to period T1, after the analog to digital conversion device 100 of the present disclosure adds the second slope signal Vslope2, the point P1 where the output signal is generated occurs earlier than the point P2 where only the first slope signal Vslope1 is used. In addition, referring to period T2, at point P3, the comparator circuit 130 generates the output signal com1 according to the first slope signal Vslope1 and the input signal Vi,1. At this time, the digital output provides a count result of Dcnt[3:0].

In some embodiments, when the at least one first slope of the first slope signal Vslope1 is positive, the at least one second slope of the second slope signal Vslope2 is negative. When the at least one first slope of the first slope signal Vslope1 is negative, the at least one second slope of the second slope signal Vslope2 is positive. For example, during a first period T11, the slope of the first slope signal Vslope1 is positive, and the slope of the second slope signal Vslope2 is negative. During a second period T12, the slope of the first slope signal Vslope1 is negative, and the slope of the second slope signal Vslope2 is positive.

In some embodiments, the voltage range Vr includes a low voltage level V1 and a high voltage level V2, and the at least one first slope of the first slope signal Vslope1 includes a first positive slope and a first negative slope. The first slope signal Vslope1 ramps up from the low voltage level V1 to the high voltage level V2 with the first positive slope during a first period T11, and then ramps down from the high voltage level V2 to the low voltage level V1 with the first negative slope during a second period T12.

In some embodiments, the at least one second slope of the second slope signal Vslope2 includes a second positive slope and a second negative slope. The second slope signal Vslope2 ramps down from the high voltage level V2 to the low voltage level V1 with the second negative slope during the first period T11, and then ramps up from the low voltage level V1 to the high voltage level V2 with the second positive slope during the second period T12.

In some embodiments, the comparator circuit 130 generates an output signal according to a rising period of the first slope signal Vslope1 and the input signal. In some embodiments, the comparator circuit 130 generates the output signal according to a falling period of the second slope signal Vslope2 and the input signal.

In some embodiments, referring to FIG. 1, the first slope signal generator circuit 110 includes a first output terminal Out1, a first switch SW1, and a second switch SW2. The first switch SW1 includes a first terminal (e.g., upper terminal) and a second terminal (e.g., lower terminal). The first terminal (e.g., upper terminal) of the first switch SW1 is configured to receive a current source current I. The second terminal (e.g., lower terminal) of the first switch SW1 is coupled to the first output terminal Out1. The second switch SW2 includes a first terminal (e.g., upper terminal) and a second terminal (e.g., lower terminal). The first terminal (e.g., upper terminal) of the second switch SW2 is coupled to the first output terminal Out1. The second terminal (e.g., lower terminal) of the second switch SW2 is configured to receive the low voltage level V1 as shown in FIG. 3. The first switch SW1 and the second switch SW2 are configured to output the first slope signal Vslope1 according to a first control signal Scon1 and a first reset signal Sre1. For example, when the first control signal Scon1 is at a high level, the first slope signal Vslope1 gradually charges toward the high voltage level V2 as shown in FIG. 3. When the first reset signal Sre1 is at a high level, the first slope signal Vslope1 is reset to the low voltage level V1.

In some embodiments, referring to FIG. 1, the second slope signal generator circuit 120 includes a second output terminal Out2, a third switch SW3, and a fourth switch SW4. The third switch SW3 includes a first terminal (e.g., upper terminal) and a second terminal (e.g., lower terminal). The first terminal (e.g., upper terminal) of the third switch SW3 receives the high voltage level V2 as shown in FIG. 3. The second terminal (e.g., lower terminal) of the third switch SW3 is coupled to the second output terminal Out2. The fourth switch SW4 includes a first terminal (e.g., upper terminal) and a second terminal (e.g., lower terminal). The first terminal (e.g., upper terminal) of the fourth switch SW4 is coupled to the second output terminal Out2. The second terminal (e.g., lower terminal) of the fourth switch SW4 is configured to receive the current source current I. The third switch SW3 and the fourth switch SW4 are configured to output the second slope signal Vslope2 according to a second control signal Scon2 and a second reset signal Sre2. For example, when the second control signal Scon2 is at a high level, the second slope signal Vslope2 gradually discharges toward the low voltage level V1 as shown in FIG. 3. When the second reset signal Sre2 is at a high level, the second slope signal Vslope2 is reset to the high voltage level V2 as shown in FIG. 3.

In some embodiments, the first switch SW1 and the fourth switch SW4 are respectively configured to output the first slope signal Vslope1 and the second slope signal Vslope2 according to the first control signal Scon1 and the second control signal Scon2, or the second switch SW2 and the third switch SW3 are respectively configured to output the first slope signal Vslope1 and the second slope signal Vslope2 according to the first reset signal Sre1 and the second reset signal Sre2. In another embodiment, referring to FIG. 1, the control signals and the reset signals may be grouped into two sets. For example, the first control signal Scon1 and the first reset signal Sre1 may form a first set, and the second control signal Scon2 and the second reset signal Sre2 may form a second set. Phases of the first control signal Scon1 and the first reset signal Sre1 may differ from phases of the second control signal Scon2 and the second reset signal Sre2. In some embodiments, referring to FIG. 1, the number of capacitors Cs3 in the present disclosure is not limited to two and may be adjusted to other suitable quantities based on actual requirements.

It should be noted that the present disclosure is not limited to the embodiments as shown in FIG. 1 to FIG. 3, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

Technical features of some embodiments of the present disclosure make an improvement to the prior art. The analog to digital conversion device and the analog to digital conversion method of the present disclosure can reduce operation latency.

It should be noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An analog to digital conversion device, comprising:
a first slope signal generator circuit, configured to generate a first slope signal, wherein the first slope signal repeatedly ramps up and down within a voltage range with at least one first slope;
a second slope signal generator circuit, configured to generate a second slope signal, wherein the second slope signal repeatedly ramps up and down within the voltage range with at least one second slope, and the at least one first slope and the at least one second slope are negatively related; and
a comparator circuit, configured to generate an output signal according to the first slope signal, the second slope signal, and an input signal.

2. The analog to digital conversion device of claim 1, wherein when the at least one first slope is positive, the at least one second slope is negative.

3. The analog to digital conversion device of claim 1, wherein when the at least one first slope is negative, the at least one second slope is positive.

4. The analog to digital conversion device of claim 1, wherein the voltage range comprises a low voltage level and a high voltage level, and the at least one first slope includes a first positive slope and a first negative slope, wherein the first slope signal ramps up from the low voltage level to the high voltage level with the first positive slope during a first period, and then ramps down from the high voltage level to the low voltage level with the first negative slope during a second period.

5. The analog to digital conversion device of claim 4, wherein the at least one second slope comprises a second positive slope and a second negative slope, wherein the second slope signal ramps down from the high voltage level to the low voltage level with the second negative slope during the first period, and then ramps up from the low voltage level to the high voltage level with the second positive slope during the second period.

6. The analog to digital conversion device of claim 1, wherein the comparator circuit generates the output signal according to a rising period of the first slope signal and the input signal.

7. The analog to digital conversion device of claim 6, wherein the comparator circuit generates the output signal according to a falling period of the second slope signal and the input signal.

8. The analog to digital conversion device of claim 5, wherein the first slope signal generator circuit comprises:
a first output terminal;
a first switch, comprising:
a first terminal, configured to receive a current source current; and
a second terminal, coupled to the first output terminal; and
a second switch, comprising:
a first terminal, coupled to the first output terminal; and
a second terminal, configured to receive the low voltage level;
wherein the first switch and the second switch output the first slope signal according to a first control signal and a first reset signal.

9. The analog to digital conversion device of claim 8, wherein the second slope signal generator circuit comprises:
a second output terminal;
a third switch, comprising:
a first terminal, configured to receive the high voltage level; and
a second terminal, coupled to the second output terminal; and
a fourth switch, comprising:
a first terminal, coupled to the second output terminal; and
a second terminal, configured to receive the current source current;
wherein the third switch and the fourth switch output the second slope signal according to a second control signal and a second reset signal.

10. The analog to digital conversion device of claim 9, wherein the first switch and the fourth switch are configured to respectively output the first slope signal and the second slope signal according to the first control signal and the second control signal, or the second switch and the third switch are configured to respectively output the first slope signal and the second slope signal according to the first reset signal and the second reset signal.

11. An analog to digital conversion method, comprising:
generating a first slope signal by a first slope signal generator circuit, wherein the first slope signal repeatedly ramps up and down within a voltage range with at least one first slope;
generating a second slope signal by a second slope signal generator circuit, wherein the second slope signal repeatedly ramps up and down within the voltage range with at least one second slope, and the at least one first slope and the at least one second slope are negatively related; and
generating an output signal according to the first slope signal, the second slope signal, and an input signal by a comparator circuit.

12. The analog to digital conversion method of claim 11, wherein when the at least one first slope is positive, the at least one second slope is negative.

13. The analog to digital conversion method of claim 11, wherein when the at least one first slope is negative, the at least one second slope is positive.

14. The analog to digital conversion method of claim 11, wherein the voltage range comprises a low voltage level and a high voltage level, and the at least one first slope includes a first positive slope and a first negative slope, wherein the first slope signal ramps up from the low voltage level to the high voltage level with the first positive slope during a first period, and then ramps down from the high voltage level to the low voltage level with the first negative slope during a second period.

15. The analog to digital conversion method of claim 14, wherein the at least one second slope comprises a second positive slope and a second negative slope, wherein the second slope signal ramps down from the high voltage level to the low voltage level with the second negative slope during the first period, and then ramps up from the low voltage level to the high voltage level with the second positive slope during the second period.

16. The analog to digital conversion method of claim 11, wherein generating the output signal according to the first slope signal, the second slope signal, and the input signal by the comparator circuit comprises:
generating the output signal according to a rising period of the first slope signal and the input signal by the comparator circuit.

17. The analog to digital conversion method of claim 16, wherein generating the output signal according to the first slope signal, the second slope signal, and the input signal by the comparator circuit comprises:
generating the output signal according to a falling period of the second slope signal and the input signal by the comparator circuit.

18. The analog to digital conversion method of claim 15, wherein the first slope signal generator circuit comprises a first output terminal, a first switch, and a second switch, wherein a first terminal of the first switch is configured to receive a current source current, a second terminal of the first switch is coupled to the first output terminal, a first terminal of the second switch is coupled to the first output terminal, and a second terminal of the second switch is configured to receive the low voltage level, wherein generating the first slope signal by the first slope signal generator circuit comprises:
outputting the first slope signal according to a first control signal and a first reset signal by the first switch and the second switch of the first slope signal generator circuit.

19. The analog to digital conversion method of claim 18, wherein the second slope signal generator circuit comprises a second output terminal, a third switch, and a fourth switch, wherein a first terminal of the third switch is configured to receive the high voltage level, a second terminal of the third switch is coupled to the second output terminal, a first terminal of the fourth switch is coupled to the second output terminal, and a second terminal of the fourth switch is configured to receive the current source current, wherein generating the second slope signal by the second slope signal generator circuit comprises:
outputting the second slope signal according to a second control signal and a second reset signal by the third switch and the fourth switch of the second slope signal generator circuit.

20. The analog to digital conversion method of claim 19, wherein the first switch and the fourth switch are configured to respectively output the first slope signal and the second slope signal according to the first control signal and the second control signal, or the second switch and the third switch are configured to respectively output the first slope signal and the second slope signal according to the first reset signal and the second reset signal.
